(19) United States
(12) Patent Application Publication
(10) Pub. No.: US 2016/0139474 A1
(43) Pub. Date: May 19, 2016

(54) LIQUID CRYSTAL DISPLAY PANEL AND ARRAY SUBSTRATE

(71) Applicant: Shenzhen China Star Optoelectronics Technology Co., Ltd., Shenzhen, Guangdong (CN)

(72) Inventors: Cheng-hung CHEN, Shenzhen, Guangdong (CN); Tien-hao CHANG, Shenzhen, Guangdong (CN); Jinbo GUO, Shenzhen, Guangdong (CN)

(73) Assignee: Shenzhen China Star Optoelectronics TEchnology Co., Shenzhen, Guangdong (CN)

(21) Appl. No.: 14/426,363

(22) PCT Filed: Nov. 21, 2014
(86) PCT No.: PCT/CN2014/091895

§ 371 Date: Mar. 5, 2015

(30) Foreign Application Priority Data
Nov. 18, 2014 (CN) 201410659998.6

(51) Int. Cl. G02F 1/1362; G02F 1/1335; H01L 27/12; G02F 1/1343

(52) U.S. Cl. CPC G02F 1/136286; G02F 1/134336; G02F 1/133514; H01L 27/124

(57) ABSTRACT

A liquid crystal display panel and an array substrate are disclosed. A pixel electrode of each pixel unit of the array substrate is correspondingly connected with at least one data line. The pixel electrode includes multiple regions arranged as a matrix. The data line is disposed between adjacent two columns of the regions. Accordingly, the penetration ratio and the aperture ratio of the pixel unit are increased.

### BACKGROUND OF THE INVENTION

1. Field of the Invention

The present invention relates to the liquid crystal display technology field, and more particularly to a liquid crystal display panel and an array substrate.

2. Description of Related Art

In a pixel structure of a VA (vertical alignment) type liquid crystal display (LCD) panel, data lines on an array substrate are arranged between two adjacent pixel units and are perpendicular to scanning lines. A black matrix is disposed on the color filter substrate, and the black matrix is corresponding to the data lines and the scanning lines for preventing the light leakage. To solve the reduced aperture ratio caused by the black matrix, each of the pixel units is divided into multiple domains. However, the liquid crystal molecules which are corresponding to the multiple domains encounter different electric field strength such that dark fringes are generated when the LCD panel is displaying. As a result, the penetration ratio and the aperture ratio of the pixel unit are reduced.

### SUMMARY OF THE INVENTION

Accordingly, a technology problem solved by the present embodiment is to provide a liquid crystal display panel and an array substrate in order to increase the penetration ratio and the aperture ratio of the pixel unit.

In order to solve the above technology problem, a technology solution of the present invention is: an array substrate including multiple pixel units, wherein, each of the multiple pixel units connects with one scanning line and at least two data lines; a pixel electrode of each pixel unit includes multiple regions arranged as a matrix; and wherein, in each pixel unit, distances between two adjacent data lines are different; data lines are disposed between adjacent two columns of the regions; along a vertical direction, heights of the regions of the pixel electrode are not equal; along an extension direction which is perpendicular to the data line, widths of the regions of the pixel electrode are equal.

In order to solve the above technology problem, a technology solution of the present invention is: an array substrate including multiple pixel units, wherein, a pixel electrode of each multiple pixel unit connects with at least one data line; the pixel electrode of each pixel unit includes multiple regions arranged as a matrix; the at least one data line is disposed between adjacent two columns of the regions.

Wherein, the pixel electrode of each pixel unit connects with one data line; the pixel electrode of each pixel unit includes a first region, a second region, a third region, and a fourth region; the first region and the second region are disposed side by side; the first region and the fourth region are disposed as a diagonal arrangement; the second region and the third region are disposed as a diagonal arrangement; the one data line is disposed between the first region and the second region, and is also disposed between the third region and the fourth region.

Wherein, an arrangement direction of an electrode pattern of the first region and an arrangement direction of an electrode pattern of the fourth region are the same; an arrangement direction of an electrode pattern of the second region and an arrangement direction of an electrode pattern of the third region are the same.

Wherein, an arrangement direction of an electrode pattern of the first region and an arrangement direction of an electrode pattern of the fourth region form a first direction; an arrangement direction of an electrode pattern of the second region and an arrangement direction of an electrode pattern of the third region form a second direction; wherein, the first direction and the second direction are perpendicular to each other.

Wherein, an area of the first region, an area of the second region, an area of the third region, and an area of the fourth region are the same.

Wherein, the pixel electrode includes multiple strip-shaped gaps, multiple first strip shape patterns, a second electrode pattern, and a third electrode pattern; the gaps and the first strip shape patterns are disposed alternately; the second electrode pattern surrounds the first region, the second region, the third region, and the fourth region; the third electrode pattern is used for defining the first region, the second region, the third region, and the fourth region.

Wherein, the pixel electrode of each pixel unit connects with at least two data lines; along a vertical direction, heights of the regions of the pixel electrode are not equal; along an extension direction which is perpendicular to the data line, widths of the regions of the pixel electrode are equal.

Wherein, in each pixel unit, distances between two adjacent data lines are different.

Wherein, the pixel electrode of each pixel unit connects with one scanning line.

In order to solve the above technology problem, a technology solution of the present invention is: a liquid crystal display (LCD) panel, comprising: a liquid crystal layer; a color filter substrate; and an array substrate; wherein, the color filter substrate and the array substrate are disposed oppositely with an interval; the liquid crystal layer is filled between color filter substrate and the array substrate; and wherein the array substrate including multiple pixel units; a pixel electrode of each multiple pixel unit connects with at least one data line; the pixel electrode of each pixel unit includes multiple regions arranged as a matrix; the at least one data line is disposed between adjacent two columns of the regions.

The beneficial effects of the present invention: through disposing the data lines between adjacent two columns of the regions, the opaque data lines are overlapped with the dark fringes between the multiple regions when the LCD panel is displaying. As a result, the light-shielding area corresponding to the data line is reduced, that is, the light-transparent area corresponding to the data line is increased. Accordingly, the penetration ratio and the aperture ratio of the pixel unit and the liquid crystal display panel having the pixel unit are increased.

### BRIEF DESCRIPTION OF THE DRAWINGS

FIG. 1 is a cross-sectional view of a liquid crystal display panel (LCD) according to a preferred embodiment of the present invention;

FIG. 2 is a schematic diagram of pixel units of an LCD panel according to a first embodiment of the present invention;

FIG. 3 is a schematic diagram of one pixel unit of an LCD panel shown in FIG. 2;

FIG. 4 is a schematic diagram of one pixel unit of an LCD panel according to a second embodiment of the present invention; and

FIG. 5 is a schematic diagram of one pixel unit of an LCD panel according to a third embodiment of the present invention.

### DETAILED DESCRIPTION OF THE PREFERRED EMBODIMENT

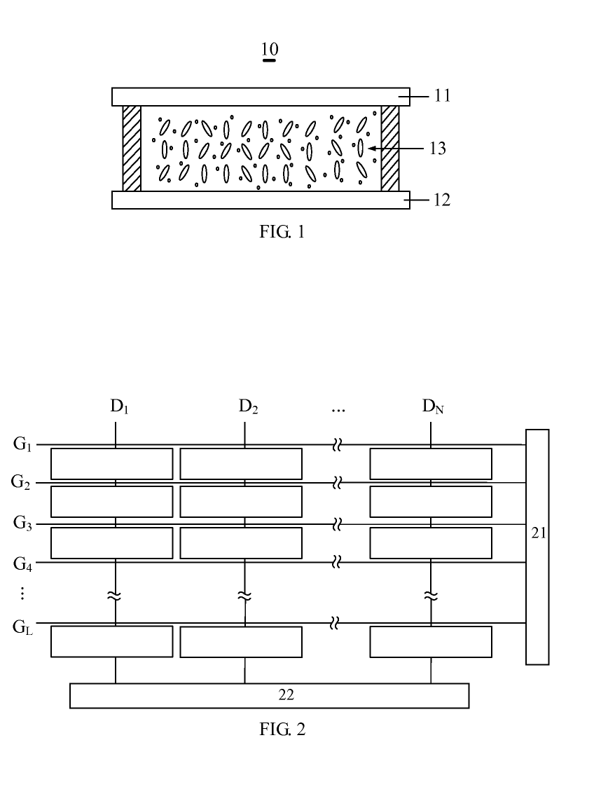

FIG. 1 is a cross-sectional view of a liquid crystal display panel (LCD) according to a preferred embodiment of the present invention. FIG. 2 is a schematic diagram of pixel units of an LCD panel according to a first embodiment of the present invention. With reference to FIG. 1 and FIG. 2, the liquid crystal display (LCD) panel 10 includes a first substrate 11, a second substrate 12 and a liquid crystal layer 13 disposed between the first substrate 11 and the second substrate 12. Wherein, the first substrate 11 and the second substrate 12 are disposed oppositely with an interval. The second substrate 12 is a color filter (CF) substrate. The first substrate 11 is a thin-film-transistor array substrate. The first substrate 11 includes a transparent substrate, pixel electrodes and wirings disposed on the substrate.

The first substrate 11 includes multiple data lines D₁, D₂, . . . , D_{N}, multiple scanning lines G₁, G₂, . . . , G_{L} which are perpendicular to the multiple data lines, and multiple pixel units P₁ , P₂, . . . , P_{X} which are defined by the multiple data lines D₁, D₂, . . . D_{N} and the multiple scanning lines G₁, G₂, . . . , G_{L}. Each of the pixel units connects with a corresponding scanning line and a corresponding data line.

Wherein, the multiple scanning lines G₁, G₂ . . . G_{L} are connected with a gate driver 21, the multiple data lines D₁, D₂ . . . D_{N} are connected with a source driver 22. The gate driver 21 provides a scanning voltage to the multiple pixel units P₁, P₂ . . . P_{X}. The source driver 22 provides a driving voltage to the multiple pixel units P₁, P₂ . . . P_{X}.

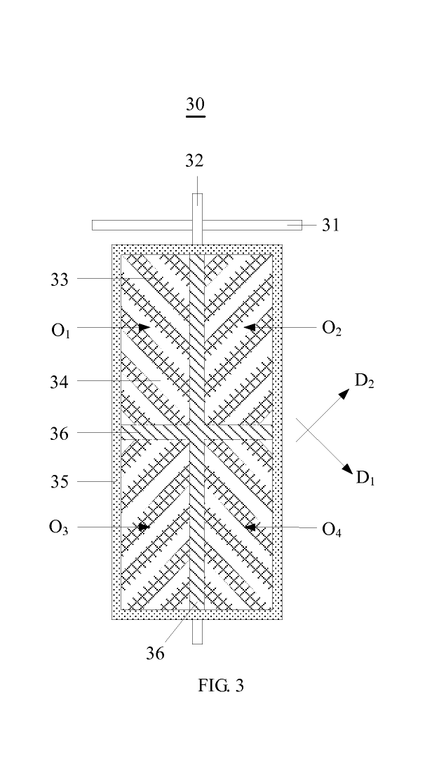

FIG. 3 is a schematic diagram of one pixel unit of an LCD panel shown in FIG. 2. With reference to FIG. 3, a pixel electrode of one pixel unit 30 of the LCD panel 10 correspondingly connects with one scanning line 31 and one data line 32. The pixel electrode of the pixel unit 30 includes multiple first strip shape patterns 33, multiple strip-shaped (ITO) gaps 34, a second electrode pattern 35, and a third electrode pattern 36.

The second electrode pattern 35 defines an aperture area of the pixel unit 30. Third electrode pattern 36 has two strips which are perpendicular to each other and form a cross shape. The third electrode pattern 36 defines the pixel electrode of the pixel unit 30 as a first region O₁, a second region O₂, a third region O₃, and a fourth region O₄ such that the pixel electrode of the pixel unit 30 is arranged as a matrix.

The first region O₁ located at upper left side and the second region O₂ located at upper right side are disposed at a same horizontal level and disposed side by side. The fourth region O₄ located at lower right side and the first region O₁ are disposed as a diagonal arrangement. The third region O₃ located at lower left side and the second region O₂ disposed as a diagonal arrangement. Preferably an area of the first region O₁, an area of the second region O₂, an area of the third region O₃, and an area of the fourth region O₄ are the same.

Furthermore, an arrangement direction of the first electrode pattern 33 of the first region O₁ and an arrangement direction of the first electrode pattern 33 of the fourth region O₄ are the same. For example, the arrangement direction is as a first direction D₁ shown in FIG. 3. An arrangement direction of the first electrode pattern 33 of the second region O₂ and an arrangement direction of the first electrode pattern 33 of the third region O₃ are the same. For example, the arrangement direction is as a second direction D₂ shown in FIG. 3. Preferably, the first direction D₁ and the second direction D₂ are perpendicular to each other. In this embodiment, the first direction D₁ and a horizontal direction form a 45 degree angle. Correspondingly, the second direction D₂ and the horizontal direction also form a 45 degree angle. Wherein, the horizontal direction means that a direction along and parallel with the scanning line 31, and from the first region O₁ toward the second region O₂, or from the third region O₃ toward the fourth region O₄.

In the pixel unit 30, the data line 32 is disposed between the first region O₁ and the second region O₂, and also disposed between the third region O₃ and the fourth region O₄. That is, the data line 32 is corresponding to the third pattern 36 and is insulated from and disposed below the third pattern 36.

In the present embodiment, for each pixel unit 30, the data line 32 is disposed between the multiple regions such that the opaque data line 32 is overlapped with the dark fringes between the multiple regions (that is, between the first region O₁ and the second region O₂, and between the third region O₃ and the fourth region O₄) when the LCD panel is displaying. As a result, the light-shielding area corresponding to the data line 32 is reduced, that is, the light-transparent area corresponding to the data line 32 is increased. Accordingly, the penetration ratio and the aperture ratio of the pixel unit 30 and the liquid crystal display panel 10 having the pixel unit 30 are increased.

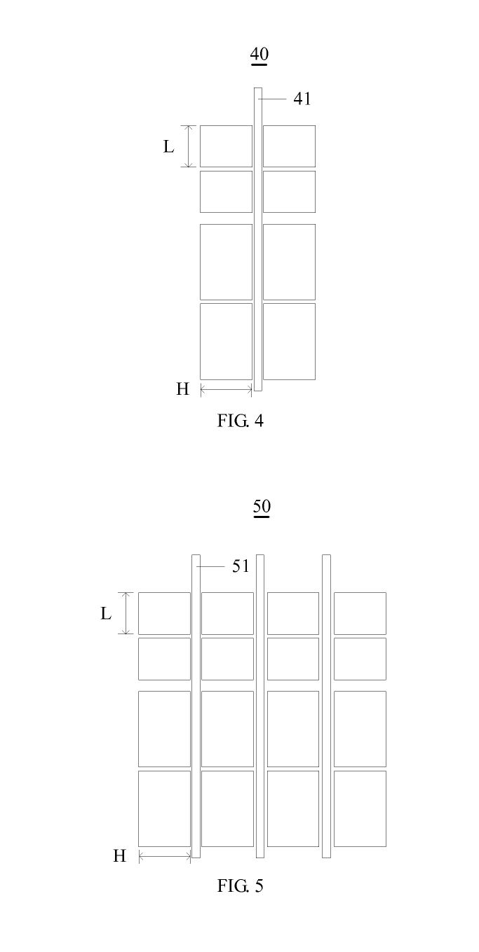

In another embodiment, as shown in FIG. 4, a pixel electrode of each pixel unit 40 has eight regions, and the pixel electrode connects with a data line 41.

As shown in FIG. 5, a pixel electrode of each pixel unit 50 includes sixteen regions. For the pixel structure as the present embodiment, the pixel electrode of each pixel unit 50 connects with three data lines 51. The data lines 51 are disposed along a vertical direction and among the multiple regions.

The distances between two adjacent data lines can be the same or not the same. Along the vertical direction, the heights L of the regions can be equal or not equal. Along an extension direction which is perpendicular to the data line, widths H of the regions can be the same or not the same. The scanning lines connected with the pixel electrode can be one or multiple. The number of the scanning lines and the electrode patterns of the regions can be determined according to the number of the thin-film transistors connected with the pixel electrode and the structure of the thin-film transistor.

In summary, the pixel electrode of each pixel unit connects with at least one data line, and the pixel electrode of each pixel unit includes multiple regions arranged as a matrix, and the data lines are disposed between adjacent two columns of the regions. As a result, the opaque data lines are overlapped with the dark fringes between the multiple regions when the LCD panel is displaying. As a result, the light-shielding area corresponding to the data line is reduced, that is, the light-transparent area corresponding to the data line is increased. Accordingly, the penetration ratio and the aperture ratio of the pixel unit and the liquid crystal display panel having the pixel unit are increased.

The above embodiments of the present invention are not used to limit the claims of this invention. Any use of the content in the specification or in the drawings of the present invention which produces equivalent structures or equivalent processes, or directly or indirectly used in other related technical fields is still covered by the claims in the present invention.

What is claimed is:

1. An array substrate including multiple pixel units,
wherein, each of the multiple pixel units connects with one scanning line and at least two data lines; a pixel electrode of each pixel unit includes multiple regions arranged as a matrix; and
wherein, in each pixel unit, distances between two adjacent data lines are different; data lines are disposed between adjacent two columns of the regions; along a vertical direction, heights of the regions of the pixel electrode are not equal; along an extension direction which is perpendicular to the data line, widths of the regions of the pixel electrode are equal.

2. An array substrate including multiple pixel units,
wherein, a pixel electrode of each multiple pixel unit connects with at least one data line; the pixel electrode of each pixel unit includes multiple regions arranged as a matrix; the at least one data line is disposed between adjacent two columns of the regions.

3. The array substrate according to claim 2, wherein, the pixel electrode of each pixel unit connects with one data line; the pixel electrode of each pixel unit includes a first region, a second region, a third region, and a fourth region; the first region and the second region are disposed side by side; the first region and the fourth region are disposed as a diagonal arrangement; the second region and the third region are disposed as a diagonal arrangement; the one data line is disposed between the first region and the second region, and is also disposed between the third region and the fourth region.

4. The array substrate according to claim 3, wherein, an arrangement direction of an electrode pattern of the first region and an arrangement direction of an electrode pattern of the fourth region are the same; an arrangement direction of an electrode pattern of the second region and an arrangement direction of an electrode pattern of the third region are the same.

5. The array substrate according to claim 3, wherein, an arrangement direction of an electrode pattern of the first region and an arrangement direction of an electrode pattern of the fourth region form a first direction; an arrangement direction of an electrode pattern of the second region and an arrangement direction of an electrode pattern of the third region form a second direction; wherein, the first direction and the second direction are perpendicular to each other.

6. The array substrate according to claim 3, wherein, an area of the first region, an area of the second region, an area of the third region, and an area of the fourth region are the same.

7. The array substrate according to claim 3, wherein, the pixel electrode includes multiple strip-shaped gaps, multiple first strip shape patterns, a second electrode pattern, and a third electrode pattern; the gaps and the first strip shape patterns are disposed alternately; the second electrode pattern surrounds the first region, the second region, the third region, and the fourth region; the third electrode pattern is used for defining the first region, the second region, the third region, and the fourth region.

8. The array substrate according to claim 2, wherein, the pixel electrode of each pixel unit connects with at least two data lines; along a vertical direction, heights of the regions of the pixel electrode are not equal; along an extension direction which is perpendicular to the data line, widths of the regions of the pixel electrode are equal.

9. The array substrate according to claim 2, wherein, in each pixel unit, distances between two adjacent data lines are different.

10. The array substrate according to claim 2, wherein, the pixel electrode of each pixel unit connects with one scanning line.

11. A liquid crystal display (LCD) panel, comprising:
a liquid crystal layer;
a color filter substrate; and
an array substrate;
wherein, the color filter substrate and the array substrate are disposed oppositely with an interval; the liquid crystal layer is filled between color filter substrate and the array substrate; and
wherein the array substrate including multiple pixel units; a pixel electrode of each multiple pixel unit connects with at least one data line; the pixel electrode of each pixel unit includes multiple regions arranged as a matrix; the at least one data line is disposed between adjacent two columns of the regions.

12. The LCD panel according to claim 11, wherein, the pixel electrode of each pixel unit connects with one data line; the pixel electrode of each pixel unit includes a first region, a second region, a third region, and a fourth region; the first region and the second region are disposed side by side; the first region and the fourth region are disposed as a diagonal arrangement; the second region and the third region are disposed as a diagonal arrangement; the one data line is disposed between the first region and the second region, and is also disposed between the third region and the fourth region.

13. The LCD panel according to claim 12, wherein, an arrangement direction of an electrode pattern of the first region and an arrangement direction of an electrode pattern of the fourth region are the same; an arrangement direction of an electrode pattern of the second region and an arrangement direction of an electrode pattern of the third region are the same.

14. The LCD panel according to claim 12, wherein, an arrangement direction of an electrode pattern of the first region and an arrangement direction of an electrode pattern of the fourth region form a first direction; an arrangement direction of an electrode pattern of the second region and an arrangement direction of an electrode pattern of the third region form a second direction; wherein, the first direction and the second direction are perpendicular to each other.

15. The LCD panel according to claim 12, wherein, an area of the first region, an area of the second region, an area of the third region, and an area of the fourth region are the same.

16. The LCD panel according to claim 12, wherein, the pixel electrode includes multiple strip-shaped gaps, multiple first strip shape patterns, a second electrode pattern, and a third electrode pattern; the gaps and the first strip shape patterns are disposed alternately; the second electrode pattern surrounds the first region, the second region, the third region, and the fourth region; the third electrode pattern is used for defining the first region, the second region, the third region, and the fourth region.

17. The LCD panel according to claim 11, wherein, the pixel electrode of each pixel unit connects with at least two data lines; along a vertical direction, heights of the regions of the pixel electrode are not equal; along an extension direction which is perpendicular to the data line, widths of the regions of the pixel electrode are equal.

18. The LCD panel according to claim 11, wherein, in each pixel unit, distances between two adjacent data lines are different.

19. The LCD panel according to claim 11, wherein, the pixel electrode of each pixel unit connects with one scanning line.
